(19) United States
(12) Patent Application Publication
(10) Pub. No.: US 2013/0038583 A1
(43) Pub. Date: Feb. 14, 2013

(54) SHIFT REGISTER CIRCUIT, DISPLAY DEVICE, AND METHOD FOR DRIVING SHIFT REGISTER CIRCUIT

(71) Applicants: Junya Shimada, Osaka-shi (JP); Shinya Tanaka, Osaka-shi (JP); Tetsuo Kikuchi, Osaka-shi (JP); Chikao Yamasaki, Osaka-shi (JP); Masahiro Yoshida, Osaka-shi (JP); Satoshi Horiuchi, Osaka-shi (JP); Isao Ogasawara, Osaka-shi (JP)

(72) Inventors: Junya Shimada, Osaka-shi (JP); Shinya Tanaka, Osaka-shi (JP); Tetsuo Kikuchi, Osaka-shi (JP); Chikao Yamasaki, Osaka-shi (JP); Masahiro Yoshida, Osaka-shi (JP); Satoshi Horiuchi, Osaka-shi (JP); Isao Ogasawara, Osaka-shi (JP)

(21) Appl. No.: 13/642,894

(22) PCT Filed: Jan. 28, 2011
(86) PCT No.: PCT/JP2011/051797

§ 371 Date: Oct. 23, 2012

(30) Foreign Application Priority Data
Apr. 28, 2010 (JP) 2010-104273

(51) Int. Cl. G11C 19/00; G06F 3/038; G09G 3/36

(52) U.S. Cl. 345/204; 377/67; 345/100

(57) ABSTRACT

Provided is a shift register circuit which includes: first through N-th circuit sections (1a, 1b) (N is an integer equal to or larger than 2) in each of which a plurality of shift register stages (SR1, SR2, . . . , SRn) are connected in cascade; and supply wires (10b, 10c, 10e, 10f). Each of the first through N-th circuit sections (1a, 1b) receives drive signals (CKA1, CKA2, CKB1, CKB2) for driving the shift register stages (SR1, SR2, . . . , SRn) via supply wires (10b, 10c, 10e, 10f) exclusive for the each of the first through N-th circuit sections (1a, 1b).

### TECHNICAL FIELD

The present invention relates to a shift register circuit that is monolithically built into a display panel.

### BACKGROUND ART

In recent years, the fabrication of a monolithic gate driver has been developed for the purpose of cost reduction. The monolithic gate driver is such a gate driver that is formed from amorphous silicon on a liquid crystal panel. The term “monolithic gate driver” is also associated with the terms such as “gate driver-free”, “built-in gate driver in panel”, and “gate in panel”.

FIG. 13 illustrates an exemplary configuration of a shift register circuit 100 constituting a monolithic gate driver.

The shift register circuit 100 has stages (shift register stages) SRk (k is a natural number which satisfies 1≦k≦n). Each of the stages SRk includes a set terminal SET, an output terminal GOUT, a reset terminal RESET, a Low power supply input terminal VSS, and clock input terminals CLK1 and CLK2. To the set terminal SET of each of the stages SRk (k≧2), an output signal Gk−1 of a preceding stage SRk−1 is supplied. To the set terminal SET of the initial stage SR1, a gate start pulse signal GSP is supplied. The output terminal GOUT of each of the stages SRk (k≧1) supplies an output signal Gk to a corresponding scanning signal line disposed in an active region 101. To the reset terminal RESET of each of the stages SRk (k≦n−1), an output signal Gk+1 of a succeeding stage SRk+1 is supplied. To the reset terminal RESET of the final stage SRn, a clear signal CLR is supplied.

To the Low power supply input terminal VSS, a Low power supply voltage VSS, which is a low-electric-potential-side power supply voltage in each stage SRk, is supplied. To one of the clock input terminal CLK1 and the clock terminal CLK2, a clock signal CKA1 is supplied, and to the other one of the clock input terminal CLK1 and the clock terminal CLK2, a clock signal CKA2 is supplied. Such clock signals supplied to the clock input terminal CLK1 and the clock input terminal CLK2 are reversed between adjacent stages.

The clock signals CKA1 and CKA2 have such complementary phases that their active clock pulses (here, high level periods) do not overlap each other, as illustrated in FIG. 14. A High level side (active side) voltage of the clock signals CKA1 and CKA2 is VGH, and a Low level side (non-active side) voltage of the clock signals CKA1 and CKA2 is VGL. The Low power supply voltage VSS is equal to the Low level side voltage VGL of the clock signals CKA1 and CKA2. In this example, the clock signal CKA1 and the clock signal CKA2 are in reverse phases, but it is also possible that an active clock pulse period of one of the clock signal CKA1 and the clock signal CKA2 is encompassed within a non-active period of the other one (i.e., a clock duty is less than ½).

The gate start pulse signal GSP is a signal which becomes active in a first clock pulse period of 1 frame period (1F). The clear signal CLR is a signal which becomes active (here, High) in a final clock pulse period of 1 frame period (1F).

FIG. 15 illustrates an exemplary configuration of each of the stages SRk of the shift register circuit 100 of FIG. 13.

Each of the stages SRk includes five transistors T1, T2, T3, T4, and T5, and a capacitor C1. These transistors are all n-channel type TFTs.

As to the transistor T1, a gate and a drain are connected to a set terminal SET, and a source is connected to a gate of the transistor T5. As to the transistor T5, which is an output transistor of each of the stages SRk, a drain is connected to the clock input terminal CLK1, and a source is connected to the output terminal GOUT. That is, the transistor T5 serves as a transmission gate for allowing/blocking passage of a clock signal to be supplied to the clock input terminal CLK1. The capacitor C1 is connected between the gate and the source of the transistor T5. A node connected to the gate of the transistor T5 is referred to as netA.

As to the transistor T3, a gate is connected to the reset terminal RESET, a drain is connected to the node netA, and a source is connected to the Low power supply input terminal VSS. As to the transistor T4, a gate is connected to the reset terminal RESET, a drain is connected to the output terminal GOUT, and a source is connected to the Low power supply input terminal VSS.

As to the transistor T2, a gate is connected to the clock terminal CLK2, a drain is connected to the output terminal GOUT, and a source is connected to the Low power supply input terminal VSS.

Next, the following describes an operation of each of the stages SRk with reference to FIG. 16.

In 1 frame period, first, the gate start pulse signal GSP is supplied, as a shift pulse of the shift register circuit 100, to the set terminal SET of the initial stage SR1. In the shift register circuit 100, this shift pulse is transferred sequentially through the stages SRk connected in cascade, so that an active pulse of an output signal Gk is output.

In each of the stages SRk, until the shift pulse is supplied to the set terminal SET, the transistors T4 and T5 are in a high impedance state, and the transistor T2 turns on every time a clock signal supplied from the clock input terminal CLK2 becomes a High level. Accordingly, the output terminal GOUT maintains Low.

When the shift pulse is supplied to the set terminal SET, the stage SRk enters a period in which it generates a gate pulse which is an active pulse of the output signal Gk, and the transistor T1 turns on. This causes the capacitor C1 to be charged. The charging of the capacitor C1 increases an electric potential of the node netA to VGH-Vth (VGH represents a High level of the gate pulse and Vth is a threshold voltage of the transistor T1). As a result, the transistor T5 turns on, and the clock signal supplied from the clock input terminal CLK1 appears in the source of the transistor T5. Since the electric potential of the node netA rapidly increases due to a bootstrap effect of the capacitor C1 at the instant when a clock pulse (High level) is input to the clock input terminal CLK1, the transistor T5 achieves a large overdrive voltage. Consequently, almost all amplitude of VGH of the clock pulse supplied to the clock input terminal CLK1 is transmitted to the output terminal GOUT of the stage SRk, and is then output as a gate pulse.

After the input of the shift pulse to the set terminal SET is finished, the transistor T1 turns off. Then, in order to release charge retention caused by floating of the node netA and the output terminal GOUT of the stage SRk, a gate pulse of a succeeding stage SRk+1 is supplied as a reset pulse to the reset terminal RESET. This causes the transistors T3 and T4 to turn on. Accordingly, the node netA and the output terminal GOUT are connected to the Low power supply voltage VSS. Consequently, the transistor T5 turns off. After input of the reset pulse is finished, the period in which the stage SRk generates the gate pulse ends, and a period in which the output terminal GOUT maintains Low starts again.

In this way, gate pulses of output signals Gk are sequentially supplied to respective gate lines, as illustrated in FIG. 17.

Such a shift register circuit utilizing a monolithic gate driver technique is described also in Patent Literature 1, etc.

### CITATION LIST

### Patent Literature 1

Japanese Patent Application Publication, Tokukai, No. 2005-50502 A (Publication Date: Feb. 24, 2005)

### SUMMARY OF INVENTION

### Technical Problem

However, as display devices have larger sizes and higher resolution, capacitances of cross capacitors formed between signal wires for driving a display panel and a load connected to an output of a shift register stage SRk are increasing. In a case where all loads connected to a power supply which generates a gate pulse are low loads, the gate pulse has a shape close to a rectangle, as illustrated in (a) of FIG. 18. The increase in the number of cross capacitors and load causes wiring delay, leading to deformation of a waveform of the gate pulse, as illustrated in (b) of FIG. 18. The deformation of the waveform of the gate pulse causes a reduction of a High period, a deviation of an operation timing of a picture element TFT, etc. In order to solve this problem, it is necessary to secure a sufficient High period of the gate pulse and an accurate pulse timing by taking measures such as (i) increasing a size (channel width W/channel length L) of a transistor used in the shift register circuit 100 and (ii) supplying, instead of a gate pulse 105, which should originally be used, a gate pulse 106 having a larger amplitude (see (c) of FIG. 18).

Such a load on a power supply which generates a gate pulse is described below.

As illustrated in FIG. 13, as wires for signals driving the shift register circuit 100, a plurality of wires such as a wire 100a for the gate start pulse signal GSP, a wire 100b for the clock signal CKA1, a wire 100c for the clock signal CKA2, a wire 100d for the Low power supply voltage VSS, and a wire 100e for the clear signal CLR are provided on the display panel.

Among these wires 100a through 100e, the wires 100b through 100d each have (i) a main wire that is drawn out from a corresponding power supply or signal source so that it reaches the vicinity of the shift register stages SRk and (ii) branch wires that are drawn out from the main wire to the respective shift register stages SRk. FIG. 13 illustrates, as an example, a main wire 100b(1) and branch wires 100b(2) of the wire 100b and a main wire 100c(1) and branch wires 100c(2) of the wire 100c.

Since the wires 100b and 100c each having the main wire and branch wires intersect with another wire, a cross capacitor is formed between the wires. The same is true for the other wires. Further, each of the wires 100b and 100c has its wire capacitance, too. Especially, the number of parts where the cross capacitor is formed increases in proportion to an increase in the number of rows of picture elements which occurs as a panel has higher resolution. Further, in a case where each row of picture elements is constituted by picture elements of a single color, picture element rows for respective colors are necessary. This causes a great increase in the number of rows, thereby leading to a remarkable increase in the number of parts where the cross capacitor is formed.

Each of the wires 100b and 100c is connected to a shift register stage SRk via a clock input terminal CLK1, and when the shift register stage SRk output a gate pulse, each of the wires 100b and 100c is connected to a corresponding gate line GLk. That is, a clock supply is a power supply which generates a gate pulse, and the wire capacitor and the cross capacitor of the wires 100b and 100c become loads on the power supply which generates a gate pulse.

FIG. 19 illustrates an equivalent circuit of each pixel PIX in the active region 101 of FIG. 13.

Each pixel PIX is provided corresponding to an intersection of a gate line GLk and a source line SLj (j is a natural number). The pixel PIX includes a TFT110, which is a selection element, a liquid crystal capacitor Clc, and a retention capacitor Ccs. A gate of the TFT110 is connected to the gate line GLk, a source of the TFT110 is connected to the source line SLj, and a drain 110d of the TFT110 is connected to a picture element electrode 111. The liquid crystal capacitor Clc is constituted by the picture element electrode 111, a common electrode COM, and a liquid crystal layer sandwiched between the picture element electrode 111 and the common electrode COM. The retention capacitor Ccs is constituted by the drain 111d, a retention capacitor line CSL, and an insulating film sandwiched between the drain 111d and the retention capacitor line CSL.

The gate line GLk is connected to the output terminal GOUT of each of the shift register stages SRk. As is clear from FIG. 15, the gate line GLk is connected to the clock supply via the clock signal CKA1 or CKA2 of FIG. 13 during a period in which the transistor T5 is on. That is, the gate line GLk becomes a load of the clock supply. Further, the gate line GLk is connected to a power supply of the Low power supply voltage VSS at the time of reset of the shift register stage SRk. That is, the gate line GLk becomes a load of the power supply of the Low power supply voltage VSS.

Further, a cross capacitor Csgx is formed at an intersection of the gate line GLk and the source line SLj. To the cross capacitor Csgx, the liquid crystal capacitor Clc and the retention capacitor Ccs are connected during a period in which the TFT 110 is on. That is, the cross capacitor Csgx, the liquid crystal capacitor Clc, and the retention capacitor Ccs become loads of the clock supply and power supply of the Low power supply voltage VSS. Such capacitors which become loads of the clock supply and power supply of the Low power supply voltage VSS include the cross capacitors Csgx, the liquid crystal capacitors Clc, and the retention capacitors Ccs of all of the picture elements PIX connected to the source line SLj.

Further, to the gate line GLk, a gate-to-source capacitor Cgs and a gate-to-drain capacitor Cgd, each of which is a parasitic capacitor of the TFT 110, is connected. The gate-to-drain capacitor Cgd includes a parasitic capacitor formed between the gate line GLk and the picture element electrode 111. That is, the gate-to-source capacitor Cgs and the gate-to-drain capacitor Cgd become loads of the clock supply and the power supply of the Low power supply voltage VSS.

Such loads illustrated in FIG. 19 are loads within a display region.

Next, FIG. 20 illustrates how the wires 100b and 100c for the clock signals CKA1 and CKA2 and the transistors in the shift register stage SRk are connected.

The wires 100b and 100c are connected to the clock input terminals CKA and CKB, for example, in the case of the shift register stage SRk configured as illustrated in FIG. 15. Accordingly, to the wires 100b and 100c, parasitic capacitors 115, 116, 117, and 118 which are gate-to-source capacitors and gate-to-drain capacitors of the transistors T2 and T5 are connected.

Since all of such load capacitors are connected to the power supply which generates a gate pulse, deformation of a waveform of the gate pulse becomes quite large. In a case where a High period of the gate pulse becomes short due to the increase of the waveform deformation, it is impossible to secure a period for sufficiently charging the liquid crystal capacitor Clc. This hinders achievement of higher resolution display. Accordingly, in a case where a size of a transistor is increased in order to improve the waveform deformation, the transistor size becomes very large since an output transistor represented by the transistor T5 originally has a very large channel width so as to have a large electric current supply capability. The monolithic gate driver technique requires an especially large size since an element (especially amorphous silicon) of small carrier mobility is used. This is contrary to a trend towards a reduction in frame width of a display panel. Further, a large-sized element has high possibility of occurrence of a production defect in any part of the element. This hinders achievement of high panel production yield.

Further, in a case where the amplitude of the clock signals CKA1 and CKA2 is increased in order to supply the gate pulse 106 with a large amplitude as illustrated in (c) of FIG. 18, it is necessary to increase a clock power supply voltage. This is contrary to the trend towards a reduction in power supply voltage for lower power consumption and higher operation speed.

In view of such circumstances, possible realistic measures against deformation of a waveform of a gate pulse are limited to an insufficient increase in transistor size which allows only a minimum electric current supply capability and an insufficient increase in power supply voltage for suppressing power consumption to a minimum. The former method, however, reduces a margin of the electric current supply capability of the transistor, thereby lowering a upper limit of a load that can be driven. The latter method leaves no sufficient margin for the power supply voltage which generates a gate pulse to drive a transistor.

As described above, a conventional shift register circuit has a problem that a sufficient operation margin cannot be secured.

The present invention was attained in view of the above problems, and an object of the present invention is to provide a shift register circuit which makes it possible to secure a sufficient operation margin, a display device including the shift register circuit, and a method for driving the shift register circuit.

### Solution to Problem

A shift register circuit of the present invention includes: first through N-th circuit sections (N is an integer equal to or larger than 2) in each of which a plurality of shift register stages are connected in cascade; and supply wires, each of the first through N-th circuit sections receiving a drive signal for driving the plurality of shift register stages via a supply wire exclusive for said each of the first through N-th circuit sections out of the supply wires.

According to the invention, the number of intersections of each of the supply wires for supplying a drive signal and another wire greatly declines. This makes it possible to greatly reduce the number of cross capacitors per supply wire for supplying a drive signal. Further, the number of shift register stages connected to each of the supply wires for supplying a drive signal greatly declines. This allows a great reduction in sum of parasitic capacitors in connection parts with the shift register stages. Accordingly, a drive signal that is supplied from a drive signal source to each of the supply wires for supplying a drive signal can have a waveform with smaller deformation, and therefore a waveform of an output signal from each of the shift register stages can have a waveform with smaller deformation, as compared with a conventional art. Consequently, it is possible to increase a charging ratio of a load without increasing a voltage range of the drive signal source nor increasing a transistor size (channel width), thereby increasing an operation margin of the shift register stages.

It is thus possible to provide a shift register circuit that makes it possible to secure a sufficient operation margin.

A method of the present invention for driving a shift register circuit which includes first through N-th circuit sections (N is an integer equal to or larger than 2) in each of which a plurality of shift register stages are connected in cascade, includes the step of supplying, to each of the first through N-th circuit sections, a drive signal for driving the plurality of shift register stages via a supply wire exclusive for said each of the first through N-th circuit sections.

According to the invention, it is possible to provide a method for driving a shift register circuit that makes it possible to secure a sufficient operation margin.

### Advantageous Effects of Invention

A shift register circuit of the present invention includes: first through N-th circuit sections (N is an integer equal to or larger than 2) in each of which a plurality of shift register stages are connected in cascade; and supply wires, each of the first through N-th circuit sections receiving a drive signal for driving the plurality of shift register stages via a supply wire exclusive for said each of the first through N-th circuit sections out of the supply wires.

It is thus possible to provide a shift register circuit that makes it possible to secure a sufficient operation margin.

A method of the present invention for driving a shift register circuit which includes first through N-th circuit sections (N is an integer equal to or larger than 2) in each of which a plurality of shift register stages are connected in cascade, includes the step of supplying, to each of the first through N-th circuit sections, a drive signal for driving the plurality of shift register stages via a supply wire exclusive for said each of the first through N-th circuit sections.

It is thus possible to provide a method for driving a shift register circuit that makes it possible to secure a sufficient operation margin.

### BRIEF DESCRIPTION OF DRAWINGS

FIG. 1 illustrates an embodiment of the present invention, and is a block diagram illustrating a configuration of a shift register circuit of Example 1.

FIG. 2 is a timing chart explaining signals of the shift register circuit of FIG. 1.

FIG. 3 illustrates an embodiment of the present invention, and is a block diagram illustrating a configuration of a shift register circuit of Example 2.

FIG. 4 is a timing chart explaining signals of the shift register circuit of FIG. 3.

FIG. 5 illustrates an embodiment of the present invention, and is a block diagram illustrating a configuration of a shift register circuit of Example 3.

FIG. 6 is a timing chart explaining signals of the shift register circuit of FIG. 5.

FIG. 7 illustrates an embodiment of the present invention, and is a block diagram illustrating a configuration of a shift register circuit of Example 4.

FIG. 8 is a timing chart explaining signals of the shift register circuit of FIG. 7.

FIG. 9 illustrates an embodiment of the present invention, and is a block diagram illustrating a configuration of a shift register circuit of Example 5.

FIG. 10 is a timing chart explaining signals of the shift register circuit of FIG. 9.

FIG. 11 illustrates an embodiment of the present invention, and is a block diagram illustrating a configuration of a display device.

FIG. 12 illustrates an embodiment of the present invention, and is a diagram explaining a gate scan direction and a data signal supply direction of the display device. (a) through (c) of FIG. 12 are diagrams illustrating variations of the supply direction.

FIG. 13 illustrates a conventional art, and is a block diagram illustrating a configuration of a shift register.

FIG. 14 is a timing chart explaining signals of the shift register circuit of FIG. 13.

FIG. 15 is a circuit diagram illustrating a configuration of a shift register stage of FIG. 13.

FIG. 16 is a timing chart illustrating an operation of the shift register stage of FIG. 15.

FIG. 17 is a timing chart illustrating an operation of the shift register circuit of FIG. 13.

FIG. 18 illustrates a conventional art, and is a waveform diagram explaining waveform deformation. (a) of FIG. 18 is a waveform diagram illustrating a waveform with small deformation, (b) of FIG. 18 is a waveform diagram illustrating a waveform with large deformation, and (c) of FIG. 18 is a waveform diagram illustrating a waveform with improved deformation.

FIG. 19 illustrates a conventional art, and is a circuit diagram explaining parasitic capacitors formed around a picture element.

FIG. 20 illustrates a conventional art, and is a circuit diagram explaining a parasitic capacitor in a part in which a supply wire for supplying a drive signal and a shift register stage are connected to each other.

### DESCRIPTION OF EMBODIMENTS

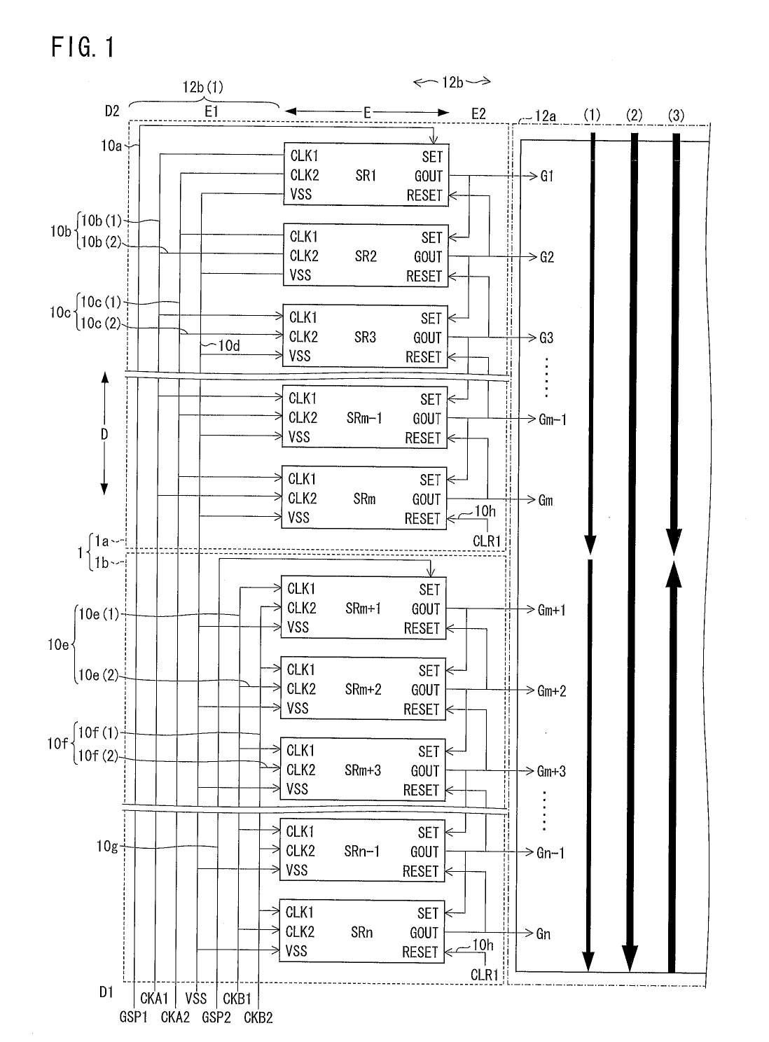

An embodiment of the present invention is described below with reference to FIGS. 1 through 12.

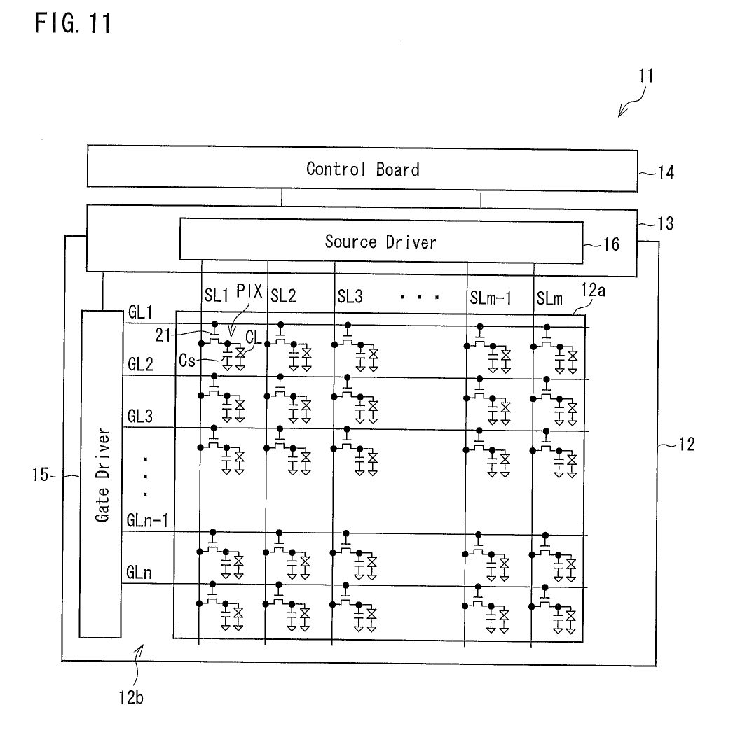

FIG. 11 illustrates a configuration of a liquid crystal display device 11 which is a display device of the present embodiment.

The liquid crystal display device 11 includes a display panel 12, a flexible printed circuit board 13, and a control board 14.

The display panel 12 is an active matrix display panel arranged such that, using TFTs produced with the use of amorphous silicon, an active region (display region) 12a, a plurality of gate lines (scanning signal lines) GL, a plurality of source lines (data signal lines) SL, and a gate driver (scanning signal line driving circuit) 15 are built onto a glass substrate. The display panel 12 may be produced with the use of TFTs formed from polycrystalline silicon, CG silicon, microcrystalline silicon, amorphous oxide semiconductor (e.g., IGZO), or the like. The active region 12a is a region where a plurality of picture elements PIX are arranged in a matrix manner. Each of the picture elements PIX includes a TFT 21 that is a selection element of the picture element, a liquid crystal capacitor CL, and an auxiliary capacitor Cs. A gate of the TFT 21 is connected to the gate line GL, and a source of the TFT 21 is connected to the source line SL. The liquid crystal capacitor CL and auxiliary capacitor Cs are connected to a drain of the TFT 21.

The plurality of gate lines GL are gate lines GL1, GL2, GL3, . . . and GLn which are connected to respective outputs of the gate driver (scanning signal line driving circuit) 15. The plurality of source lines SL are source lines SL1, SL2, SL3, . . . SLm, which are connected to respective outputs of a source driver 16 that will be described later. Although not shown, an auxiliary capacitor wire is formed to apply an auxiliary capacitor voltage to each of the auxiliary capacitors Cs of the picture elements PIX.

The gate driver 15 is provided in one of two regions adjoining the active region 12a of the display panel 12 in a direction in which the gate lines GL extend, and sequentially supplies a gate pulse (scan pulse) to each of the gate lines GL with the use of a shift register circuit provided therein. Another gate driver may be provided in the other region adjoining the active region 12a of the display panel 12 in the direction in which the gate lines GL extend, and scans gate lines GL different from those scanned by the gate driver 15. These gate drivers are formed from at least one of amorphous silicon, polycrystalline silicon, CG silicon, microcrystalline silicon, and amorphous oxide semiconductor (e.g., IGZO: In—Ga—Zn—O) and built into the display panel 12 so as to be monolithically fabricated with the active region 12a. Examples of the gate driver 15 can include all gate drivers referred to with the terms such as “monolithic gate driver”, “gate driver-free”, “built-in gate driver in panel”, and “gate in panel”.

The flexible printed circuit board 13 includes the source driver 16. The source driver 16 supplies a data signal to each of the source lines SL. The control board 14 is connected to the flexible printed circuit board 13 and supplies necessary signals and power to the gate driver 15 and the source driver 16. The signals and power to be supplied to the gate driver 15 from the control board 14 pass through the flexible printed circuit board 13 and are then supplied to the gate driver 15 on the display panel 12.

A region outside the active region 12a on the display panel 12 is a frame region 12b. The gate driver 15 is provided in the frame region 12b, and the flexible printed circuit board 13 is connected to the frame region 12b.

Such an arrangement in which a gate driver is fabricated by the monolithic gate driver technique like the gate driver 15 is suitable for a case where all picture elements PIX in a single row are picture elements of an identical color and where the gate driver 15 drives the gate lines GL on a color (R, G, or B) basis. In this case, it is unnecessary to prepare the source driver 16 for each of the colors. This is advantageous since a size of the source driver 16 and a size of the flexible printed circuit board 13 can be reduced.

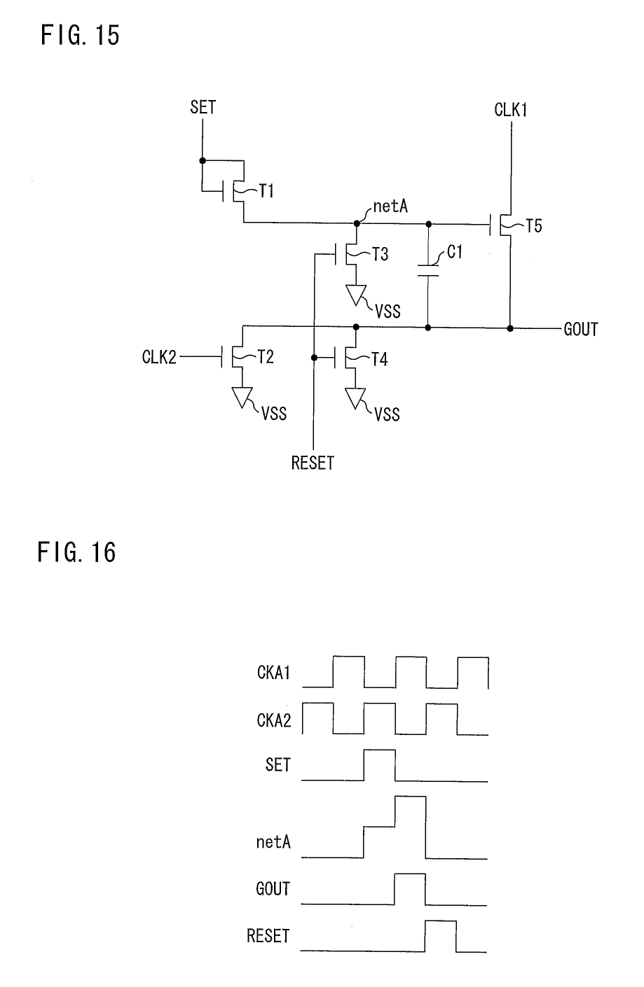

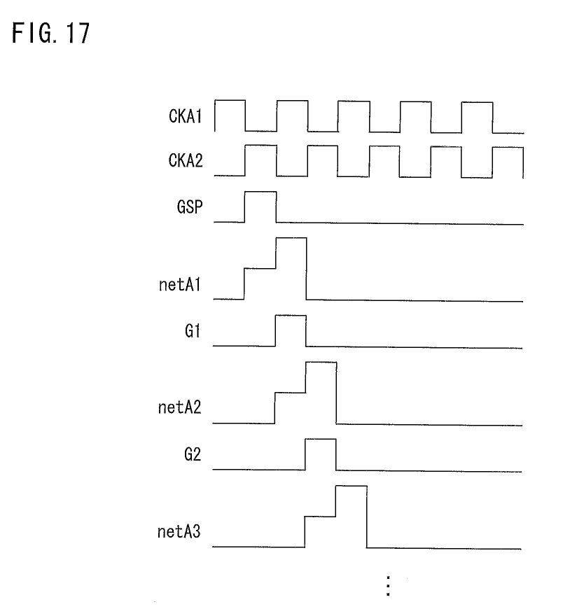

Next, the following describes a configuration of a shift register circuit provided in the gate driver 15 of the liquid crystal display device 11 configured as above, with reference to Examples. Note that each stage (shift register stage) SRk of the shift register circuit described below is not limited to a specific configuration, and can be, for example, the circuit illustrated in FIG. 15, and therefore the configuration of each stage (shift register stage) SRk of the shift register circuit is not described.

### Example 1

FIG. 1 illustrates a configuration of a shift register circuit 1 of the present example.

The shift register circuit 1 includes a first circuit section 1a, a second circuit section 1b, and wires 10a, 10b, 10c, 10d, 10e, 10f, 10g, and 10h.

The first circuit section 1a is arranged such that stages (shift register stages) SRk (k is a natural number which satisfies 1≦k≦m) are connected in cascade. Each of the stages SRk includes a set terminal SET, an output terminal GOUT, a reset terminal RESET, a Low power supply input terminal VSS, and clock input terminals CLK1 and CLK2. To the set terminal SET of each of the stages SRk (k≧2), an output signal Gk−1 from a preceding stage SRk−1 is supplied. To the set terminal SET of the initial stage SR1 of the first circuit section 1a, a gate start pulse signal GSP1 is supplied. In each of the stages SRk (1≦k≦m), the output terminal GOUT supplies an output signal Gk to a corresponding gate line GLk provided in the active region 12a. To the reset terminal RESET of each of the stages SRk (k≦m−1), an output signal Gk+1 of a succeeding stage SRk+1 is supplied. To the reset terminal RESET of the final stage SRm of the first circuit section 1a, a clear signal CLR1 is supplied.

To the Low power supply input terminal VSS, a Low power supply voltage VSS, which is a low-electric-potential-side power supply voltage in each stage SRk, is supplied. To one of the clock input terminal CLK1 and the clock terminal CLK2, a clock signal CKA1 is supplied, and to the other one of the clock input terminal CLK1 and the clock terminal CLK2, a clock signal CKA2 is supplied. Such clock signals supplied to the clock input terminal CLK1 and the clock input terminal CLK2 are reversed between adjacent stages.

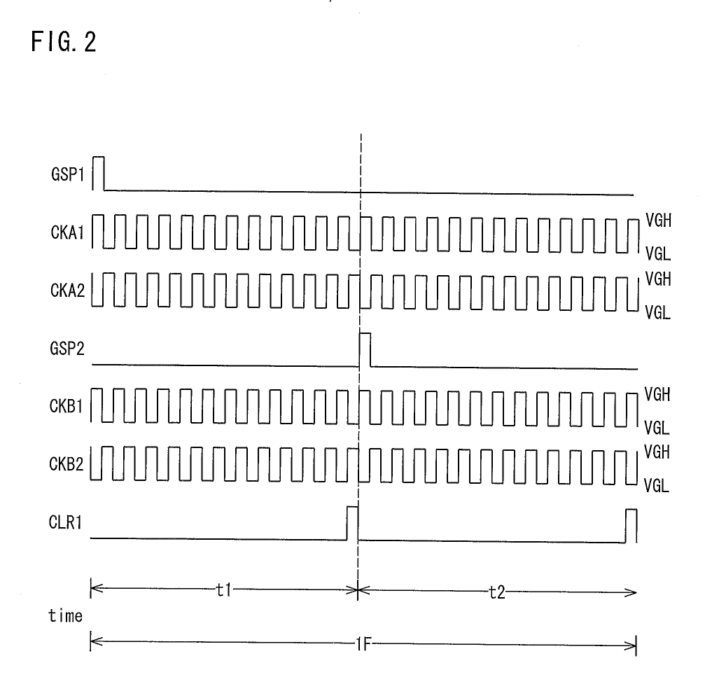

The clock signals CKA1 and CKA2 have such complementary phases that their active clock pulse periods (here, high level periods) do not overlap each other, as illustrated in FIG. 2. A High level side (active side) voltage of the clock signals CKA1 and CKA2 is VGH, and a Low level side (non-active side) voltage of the clock signals CKA1 and CKA2 is VGL. The Low power supply voltage VSS is equal to the Low level side voltage VGL of the clock signals CKA1 and CKA2. In this example, the clock signal CKA1 and the clock signal CKA2 are in reverse phases, but it is also possible that an active clock pulse period of one of the clock signal CKA1 and the clock signal CKA2 is encompassed within a non-active period of the other one (i.e., a clock duty is less than ½).

The gate start pulse signal GSP1 is a signal which becomes active in a first clock pulse period of 1 frame period (1F), i.e., a period t1 described below. The clear signal CLR1 is a signal which becomes active (here, High) twice in 1 frame period (1F) so as to reset the final stages of the first circuit section 1a and the second circuit section 1b.

The second circuit section 1b is arranged such that stages (shift register stages) SRk (k is a natural number which satisfies m+1≦k≦n) are connected in cascade. Each of the stages SRk includes a set terminal SET, an output terminal GOUT, a reset terminal RESET, a Low power supply input terminal VSS, and clock input terminals CLK1 and CLK2. To the set terminal SET of each of the stages SRk (m+2≦k≦n), an output signal Gk−1 of a preceding stage SRk−1 is supplied. To the set terminal SET of the initial stage SR1 of the second circuit section 1b, a gate start pulse signal GSP2 is supplied. In each of the stages SRk (m+1≦k≦n), the output terminal GOUT supplies an output signal Gk to a corresponding gate line GLk provided in the active region 12a. To the reset terminal RESET of each of the stages SRk (m+1≦k≦n−1), an output signal Gk+1 of a succeeding stage SRk+1 is supplied. To the reset terminal RESET of the final stage SRm of the second circuit section 1b, a clear signal CLR1 is supplied.

To the Low power supply input terminal VSS, the Low power supply voltage VSS is supplied. To one of the clock input terminal CLK1 and the clock terminal CLK2, a clock signal CKB1 is supplied, and to the other one of the clock input terminal CLK1 and the clock terminal CLK2, a clock signal CKB2 is supplied. Such clock signals supplied to the clock input terminal CLK1 and the clock input terminal CLK2 are reversed between adjacent stages.

The clock signals CKB1 and CKB2 have such complementary phases that their active clock pulse periods (here, high level periods) do not overlap each other, as illustrated in FIG. 2. A High level side (active side) voltage of the clock signals CKB1 and CKB2 is VGH, and a Low level side (non-active side) voltage of the clock signals CKB1 and CKB2 is VGL. In this example, the clock signal CKB1 is in an identical phase to the clock signal CKA1, and the clock signal CKB2 is in an identical phase to the clock signal CKA2. The Low power supply voltage VSS is equal to the Low level side voltage VGL of the clock signals CKB1 and CKB2. In this example, the clock signal CKB1 and the clock signal CKB2 are in reverse phases, but it is also possible that an active clock pulse period of one of the clock signal CKB1 and the clock signal CKB2 is encompassed within a non-active period of the other one (i.e., a clock duty is less than ½).

The gate start pulse signal GSP2 is a signal which becomes active in a first clock pulse period of a period t2, in 1 frame period (1F), which follows the period t1 for scanning in the first circuit section 1a. The clear signal CLR1 is identical to that described in the explanation of the first circuit section 1a.

In a case where a direction along a shift direction of a shift pulse in each of the first circuit section 1a and the second circuit section 1b is referred to as a direction (first direction) D, the first circuit section 1a and the second circuit section 1b are aligned in the direction D in the frame region 12b.

On the frame region 12b, a plurality of wires are formed such as the wire 10a for the gate start pulse signal GSP1, the wire 10b for the clock signal CKA1, the wire 10c for the clock signal CKA2, the wire 10d for the Low power supply voltage VSS, the wire 10e for the clock signal CKB1, the wire 10f for the clock signal CKB2, the wire 10g for the gate start pulse signal GSP2, and the wire 10h for the clear signal CLR1.

Among these wires 10a through 10g, the wires 10b through 10f each have (i) a main wire that is drawn out from a corresponding power supply or signal source so that it reaches the vicinity of the shift register stages SRk and (ii) branch wires that are drawn out from the main wire to the respective shift register stages SRk. FIG. 1 illustrates, as examples, a main wire 10b(1) and branch wires 10b(2) of the wire 10b, a main wire 10c(1) and branch wires 10c(2) of the wire 10c, a main wire 10e(1) and branch wires 10e(2) of the wire 10e, and a main wire 10f(1) and branch wires 10f(2) of the wire 10f.

In a case where a direction perpendicular to the direction D on a surface on which the circuit is formed is referred to as a direction (second direction) E, the wires 10b and 10c that respectively correspond to supply wires for the clock signals (drive signals) CKA1 and CKA2 which supply wires are exclusive for the first circuit section 1a, and the wires 10e and 10f that respectively correspond to supply wires for the clock signals CKB1 and CKB2 which supply wires are exclusive for the second circuit section 1b are provided in a region (first region) 12b(1) that is located on an E1 side (predetermined side of the second direction) which is one side of the direction E for both of the first circuit section 1a and the second circuit section 1b so as to extend from a D1 side (a predetermined side of the first direction) which is one side of the direction D towards a corresponding one of the first circuit section 1a and the second circuit section 1b.

In this example, the E1 side corresponds to an outer side of the display panel 12. Note, however, that the predetermined side of the second direction may be any one of the two sides of the direction E (e.g., the predetermined side of the second direction may be an E2 side that is an opposite side to the E1 side in a case where the shift register circuit 1 is not on board in the display device). In this example, the D1 side corresponds to a side where a clock signal source which is a drive signal source is present. Note, however, that, generally, the predetermined side of the first direction may be any one of the two sides of the direction D.

In this example, all of the wires 10a through 10h are drawn out from an outside of the display panel 12, as described with reference to FIG. 11. In this case, the wires 10a through 10h extend from the D1 side of the direction D in which the shift register circuit 1 is formed towards respective connection parts with the shift register circuit 1 (see, for example, the wires 10a through 10g illustrated in FIG. 1).

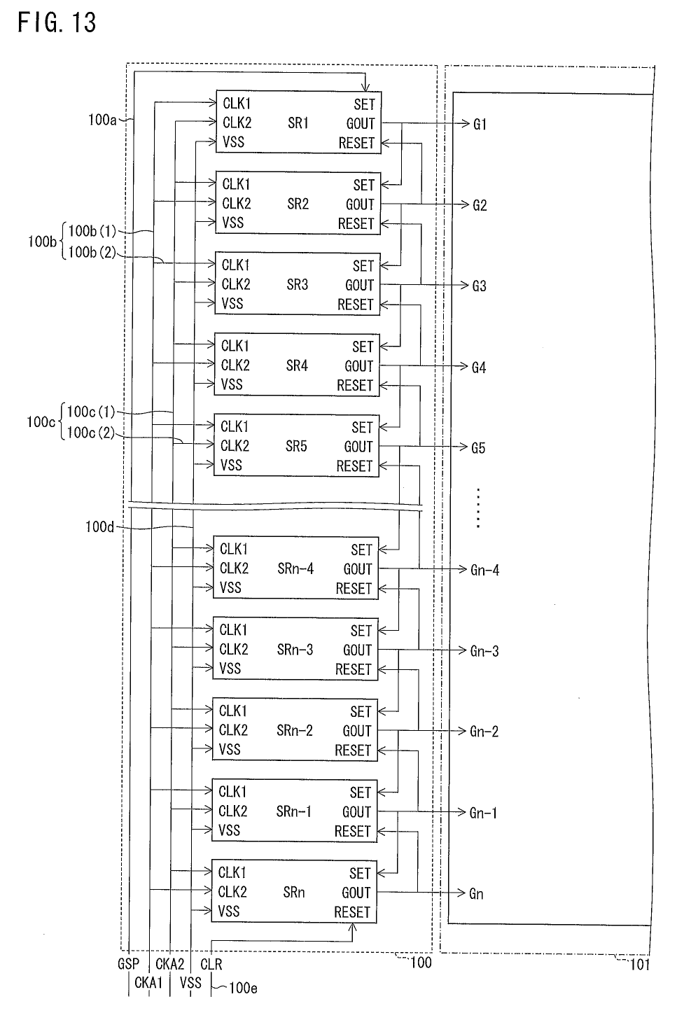

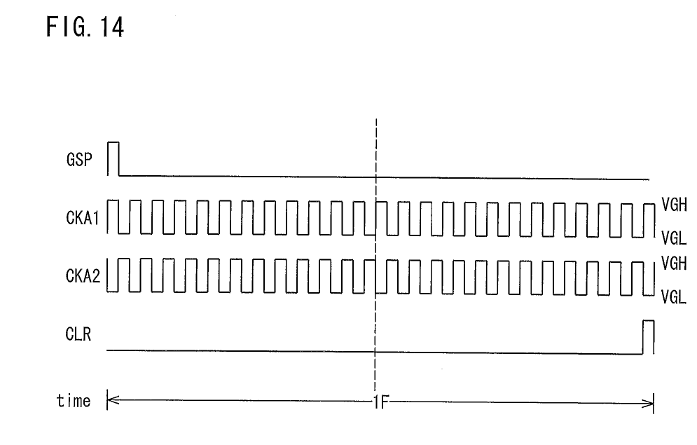

In this case, in a case where the wires 10b and 10c connected to the first circuit section 1a are disposed in an outer side of the display panel 12 than the wires 10e and 10f connected to the second circuit section 1b as illustrated in FIG. 1, there is no intersection of the wires 10b and 10c and the wires 10e and 10f. This arrangement corresponds to an arrangement in which a main wire of a supply wire corresponding to an i-th circuit section (i=1, 2) that is farther away from the D1 side when the shift register circuit 1 is viewed in the direction D is disposed closer to the E1 side of the region 12b(1). This reduces the number of intersections of the wires 10b, 10c, 10e, and 10f and another wire which occur since each of the wires 10b, 10c, 10e, and 10f which is constituted by a main wire and branch wires is connected to a corresponding shift register stage SRk, as compared with the case of the wires 100b and 100c of FIG. 13. In a case where m=(½)n, the number of intersections becomes ½.

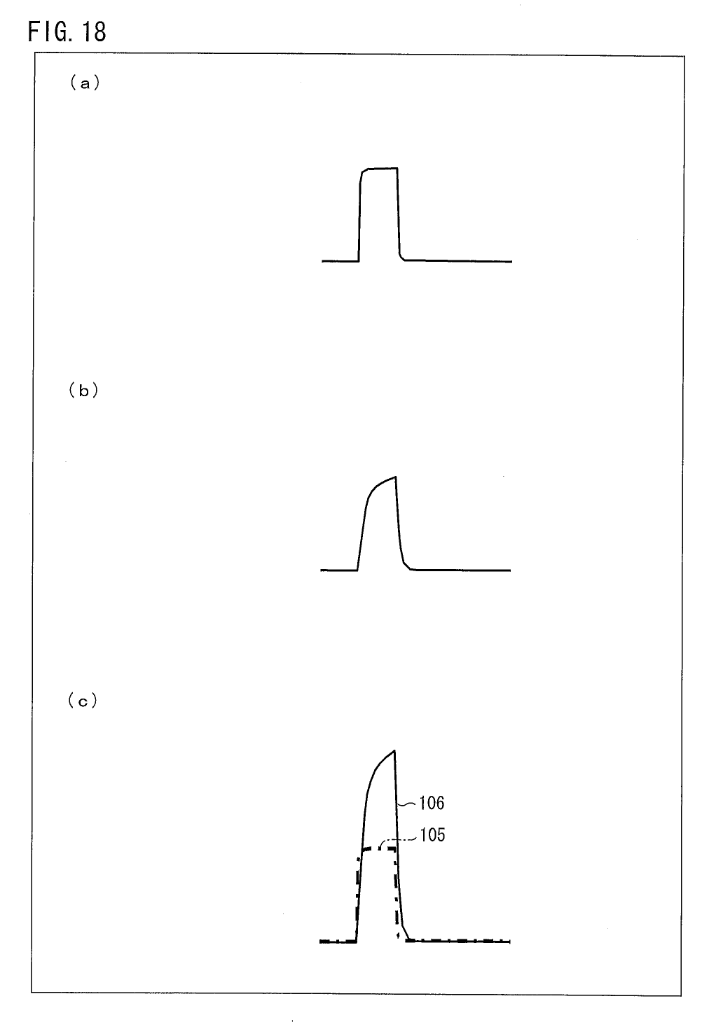

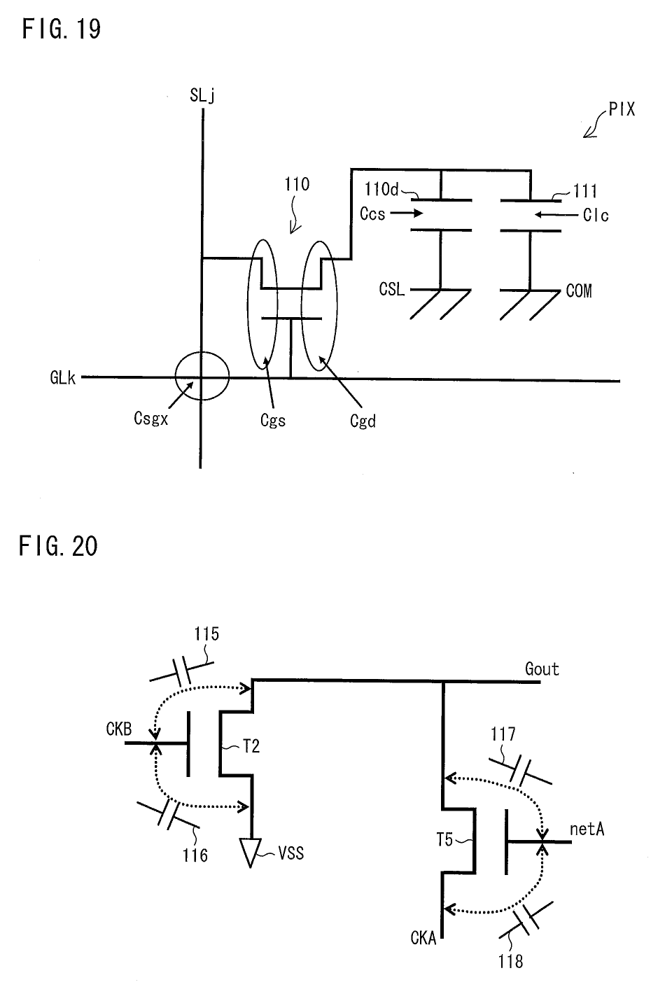

The arrangement of the present example allows a great reduction in the number of intersections of the wires 10b, 10c, 10e, and 10f and another wire, as described above. This makes it possible to greatly reduce the number of cross capacitors per supply wire for supplying a drive signal. Further, the number of shift register stages SRk connected to a single supply wire for supplying a drive signal greatly declines. This greatly reduces a sum of parasitic capacitors in connection parts with the shift register stages SRk illustrated in FIG. 20. Accordingly, a drive signal (here, a clock signal) supplied from a clock supply to a supply wire for supplying the drive signal can have a waveform with smaller deformation, and therefore an output signal of a shift register stage SRk can have a waveform with smaller deformation, as compared with a conventional art, as illustrated in (a) of FIG. 18. It is therefore possible to sufficiently secure a selection period of a picture element PIX and increase a charging ratio without increasing a voltage range of a clock supply nor increasing a transistor size (channel width). This allows an increase in operation margin of the shift register stages SRk accordingly.

It is thus possible to provide a shift register circuit which makes it possible to secure a sufficient operation margin, a display device including the shift register circuit, and a method for driving the shift register circuit.

FIG. 2 illustrates an operation of the shift register circuit 1 configured as above.

It is assumed here that m=(½)n is satisfied. The period t1 is a former half of 1 frame period (1F), and the period t2 is a latter half of 1 frame period (1F). The clear signal CLR1 becomes active in a final clock pulse period of the period t1 and in a final clock pulse period of the period t2.

Accordingly, as shown by (1) in FIG. 1, throughout 1 frame period (1F), the gate scan is carried out first in the first circuit section 1a in a direction from the D2 side towards the D1 side, and is then carried out in the second circuit section 1b in a direction from the D2 side towards the D1 side. In this case, a data signal from the source driver 16 can be supplied in a single direction, i.e., a direction from the D2 towards the D1 side as shown by (2) in FIG. 1 (or a direction from the D1 side towards the D2 side) or can be supplied in two directions, i.e., a direction from the D2 side towards the D1 side and a direction from the D1 side towards the D2 side as shown by (3) in FIG. 1.

The above description has dealt with an example in which the drive signal is a clock signal. However, the drive signal is not limited to this. The drive signal may be a drive signal for a shift register stage SRk which drive signal does not have a uniform periodicity.

The above description has dealt with an example in which the shift register circuit 1 is constituted by the first and second circuit sections. However, the present example is not limited to this. The shift register circuit 1 may be a shift register circuit that includes first through N-th circuit sections (N is an integer equal to or larger than 2) in each of which a plurality of shift register stages are connected in cascade. In a case where a direction along the shift direction is referred to as a first direction and a direction perpendicular to the first direction on a surface on which the circuit is formed is referred to as a second direction, the shift register circuit includes the first through N-th circuit sections so that the first through N-th circuit sections are aligned in the first direction. In each of the first through N-th circuit sections, the shift register stages are driven by a drive signal supplied by a supply wire exclusive for each of the first through N-th circuit sections. The number of shift register stages is determined for each of the first through N-th circuit sections. The supply wire for supplying a drive signal is provided for each of the first through N-th circuit sections. Alternatively, further, the supply wire for supplying a drive signal is disposed in a first region that is located closer, than a corresponding one of the first through N-th circuit sections, to a predetermined side of the second direction, which is one side of the second direction and which is common to all of the first through N-th circuit sections, so as to extend from a predetermined side of the first direction, which is one side of the first direction and which is common to all of the first through N-th circuit sections, towards a corresponding one of the first through N-th circuit sections.

Further, in the above example, drive signal sources are provided only in one side (e.g., D2 side). However, the present example is not limited to this. The drive signal sources may be provided both in the D1 side and the D2 side. In this case, in a case where (i) a drive signal supply wire corresponding to an i-th circuit section (i is an integer which satisfies 1≦i≦N) that is closer to the D1 side (the predetermined side of the first direction) than the D2 side (the opposite side to the predetermined side of the first direction) is disposed so as to extend from the D1 side and (ii) a drive signal supply wire corresponding to an i-th circuit section that is closer to the D2 side than the D1 side is disposed so as to extend from the D2 side, a balance is achieved between the lengths of the supply wires on the D1 side of the shift register circuit 1 and the lengths of the supply wires on the D2 side of the shift register circuit 1. Accordingly, a difference is unlikely to occur in deformation of a waveform of a drive signal, and therefore a difference is unlikely to occur in deformation of a waveform of an output signal of a shift register stage SRk.

That is, such an arrangement is possible in which (i) a drive signal supply wire corresponding to an i-th circuit section that is provided closer to the predetermined side of the first direction which is one side of the first direction is disposed so as to extend from the predetermined side of the first direction towards the corresponding i-th circuit section and (ii) a drive signal supply wire corresponding to an i-th circuit section that is provided closer to the opposite side to the predetermined side of the first direction is disposed so as to extend from the opposite side to the predetermined side of the first direction towards the corresponding i-th circuit section.

### Example 2

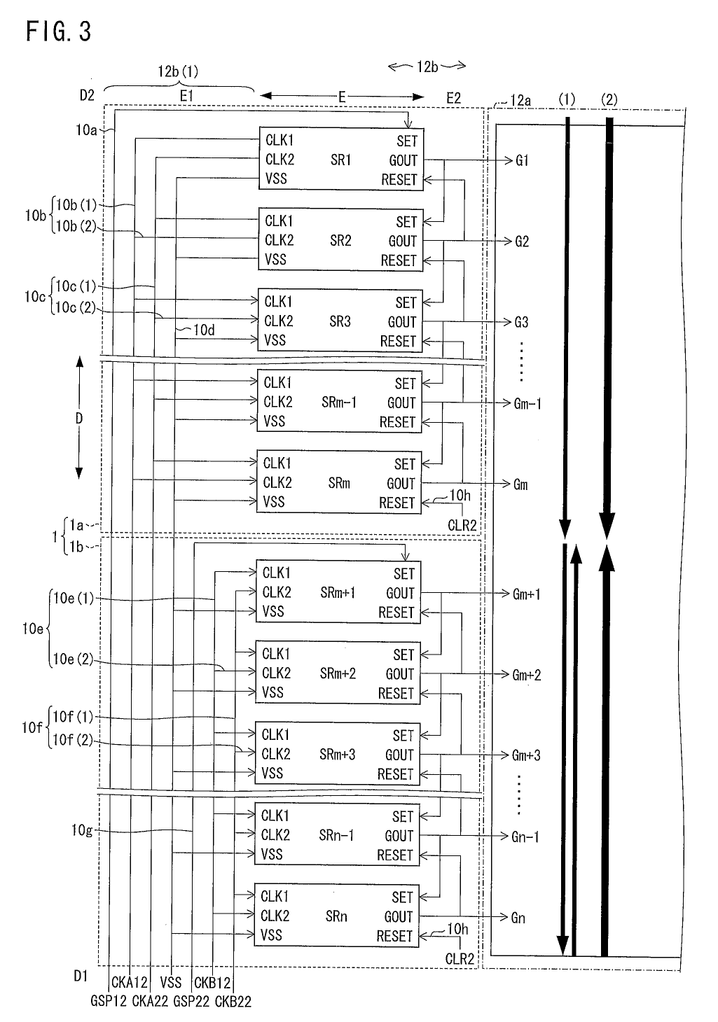

FIG. 3 illustrates a configuration of a shift register circuit 1 of the present example.

The shift register circuit 1 of FIG. 3 has an identical configuration to the shift register circuit 1 of FIG. 1. However, clock signals (drive signals) CKA12, CKA22, CKB12, and CKB22, gate start pulse signals GSP12 and GSP22, and a clear signal CLR2 are input instead of the clock signals CKA1, CKA2, CKB1, and CKB2, the gate start pulse signals GSP1 and GSP2, and the clear signal CLR1 of FIG. 1, respectively.

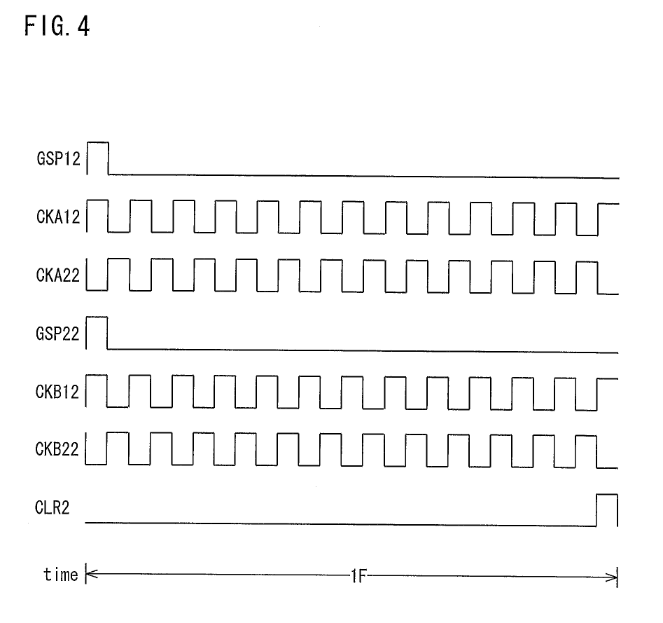

As illustrated in FIG. 4, the clock signals CKA12, CKA22, CKB12, and CKB22 have the same duty ratio as the clock signals CKA1, CKA2, CKB1, and CKB2 and have a cycle that is two times longer than that of the clock signals CKA1, CKA2, CKB1, and CKB2. The gate start pulse signals GSP1 and GSP2 become active in an initial clock pulse period of 1 frame period (1F). The clear signal CLR2 becomes active in a final clock pulse period of 1 frame period (1F).

This makes it possible to perform scan simultaneously in the first circuit section 1a and the second circuit section 1b, as shown by (1) of FIG. 3. The gate scan may be performed in a direction from the D2 side towards the D1 side both in the first circuit section 1a and the second circuit section 1b or may be performed in a direction from the D2 side towards the D1 side in the first circuit section 1a and in a direction from the D1 side towards the D2 side in the second circuit section 1b. In a case where the gate scan is performed in a direction from the D1 side towards the D2 side in the second circuit section 1b, in FIG. 3, the gate start pulse signal GSP22 is supplied to the shift register stage SRn of the second circuit section 1b in a manner reverse to the order of cascade connection, instead of supplying the gate start pulse signal GSP22 to the shift register stage SRm+1 which is the initial stage of the second circuit section 1b. In this way, a shift pulse is shifted from the D1 side towards the D2 side. In this case, the clear signal CLR2 is supplied to a reset terminal RESET of the shift register stage SRm+1 of the second circuit section 1b.

In a case where such gate scan is performed, a data signal is supplied from the source driver 16 in a direction from the D2 side towards the D1 side in the first circuit section 1a and in a direction from the D1 side towards the D2 side in the second circuit section 1b, as shown by (2) of FIG. 3.

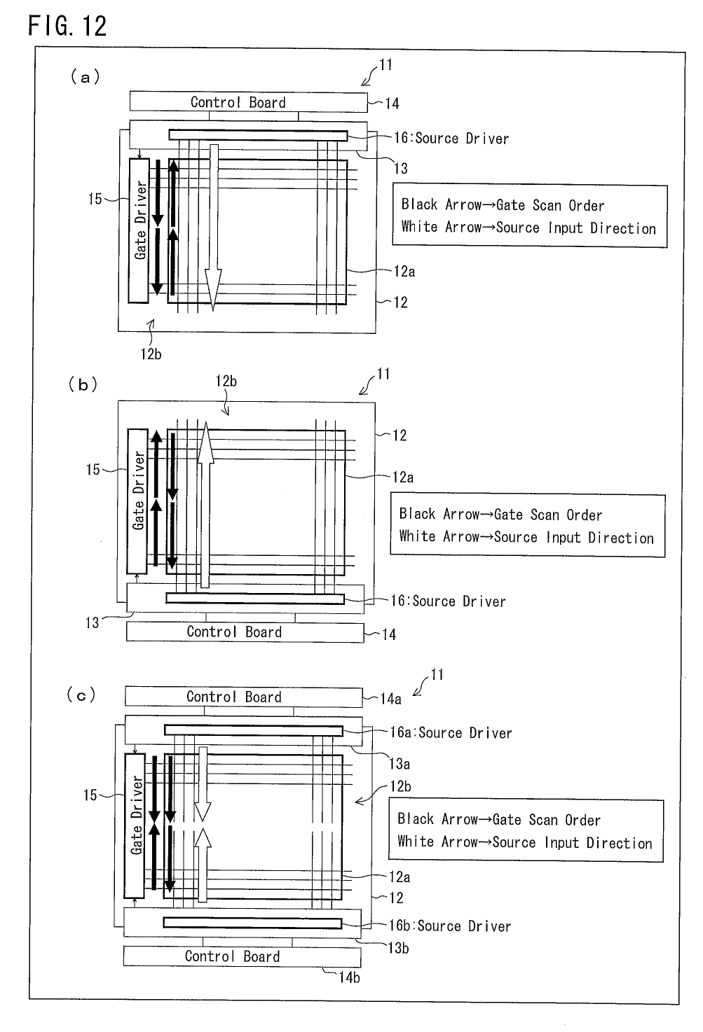

That is, of a screen which is divided into an upper screen and a lower screen, the first circuit section 1a drives the upper screen and the second circuit section 1b drives the lower screen. This corresponds to the configuration of (c) of FIG. 12 that is described later.

According to the arrangement of the present example, a cycle of a clock signal is long, and a screen is divided into upper and lower screens which are respectively driven by first through N-th circuit sections independently allocated to the upper and lower screens. This makes it possible to secure a long selection period of a picture element PIX. Accordingly, the arrangement of the present example is suitable especially for high resolution and high-speed display.

### Example 3

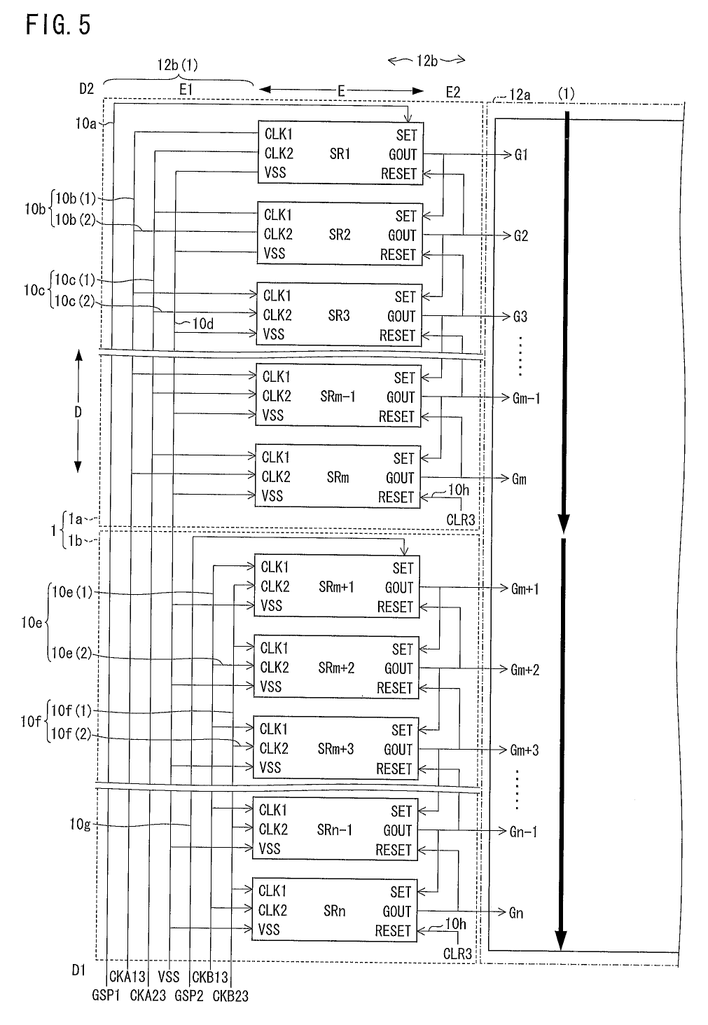

FIG. 5 illustrates a configuration of a shift register circuit 1 of the present example.

The shift register circuit 1 of FIG. 5 has an identical configuration to the shift register circuit 1 of FIG. 1. However, clock signals (drive signals) CKA13, CKA23, CKB13, and CKB23, and a clear signal CLR3 are input instead of the clock signals CKA1, CKA2, CKB1, and CKB2, and the clear signal CLR1 of FIG. 1, respectively.

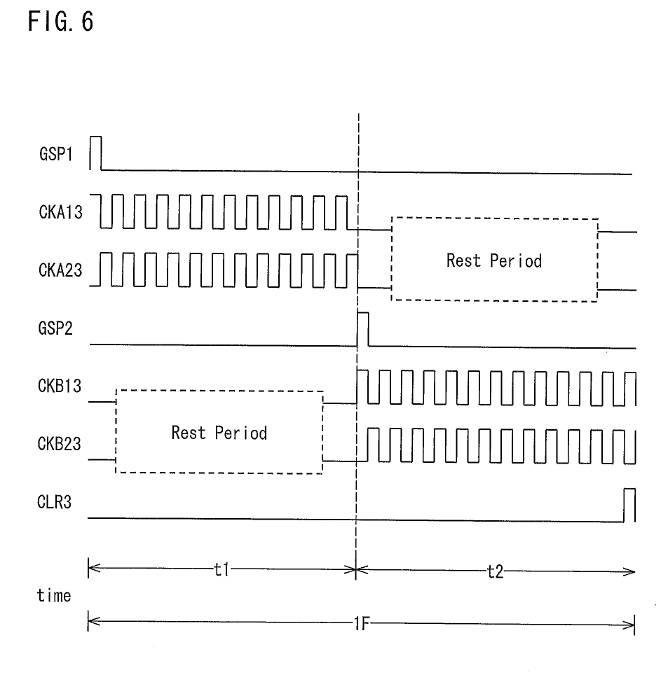

As illustrated in FIG. 6, the clock signal CKA13 and CKA23 are signals obtained by replacing the period t2 of the clock signals CKA1 and CKA2 with a rest period in which a non-active level is maintained. The clock signals CKB13 and CKB23 are signals obtained by replacing the period t1 of the clock signals CKB1 and CKB2 with a rest period in which a non-active level is maintained. The clear signal CLR3 is a signal which becomes an active level only in a final clock pulse period of 1 frame period (1F).

As shown by (1) of FIG. 6, the gate scan is performed in a direction from the D2 side towards the D1 side in the period t1 and performed in the direction from the D2 side towards the D1 side in the period t2.

As described above, in the present example, a drive signal of one circuit section has a rest period within an operation period of another circuit section. The clock signals CKA13 and CKA23 charge/discharge the wires 10b and 10c only in the period t1 which is an operation period of the first circuit section 1a, and the clock signals CKB13 and CKB23 charge/discharge the wires 10e and 10f only in the period t2 which is an operation period of the second circuit section 1b. Accordingly, the presence of the rest period reduces a loss of electricity associated with charging/discharging of the supply wires for supplying a drive signal, thereby further reducing waveform deformation. Further, a reduction in power consumption can also be achieved since an operation of a corresponding i-th circuit section is stopped in the rest period.

### Example 4

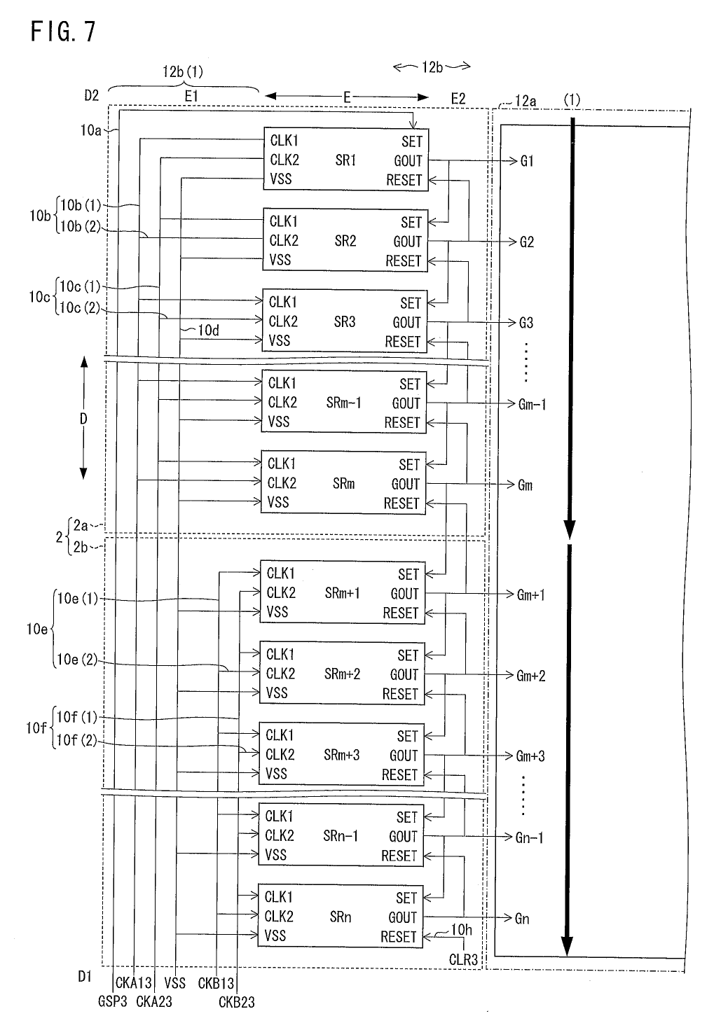

FIG. 7 illustrates a configuration of a shift register circuit 2 of the present example.

The shift register circuit 2 of FIG. 7 includes a first circuit section 2a and a second circuit section 2b.

The first circuit section 2a is different from the first circuit section 1a of FIG. 1 in that an output signal Gm+1 of a shift register stage SRm+1 which is an initial stage of the second circuit section 2b is supplied, instead of the clear signal CLR, to a reset terminal RESET of a shift register stage SRm which is the final stage of the first circuit section 2a. The second circuit section 2b is different from the second circuit section 1b of FIG. 1 in that (i) an output signal Gm of a shift register stage SRm is supplied, instead of the gate start pulse signal GSP2, to a set terminal SET of a shift register stage SRm+1 which is an initial stage of the second circuit section 2b and (ii) the output signal Gm+1 of the shift register stage SRm+1 which is the initial stage of the second circuit section 2b is supplied to the reset terminal RESET of the shift register stage SRm as described above.

To a set terminal SET of a shift register stage SR1 which is an initial stage of the first circuit section 2a, a gate start pulse signal GSP3 that is identical to the gate start pulse signal GSP1 is supplied. Further, instead of the clock signals CKA1, CKA2, CKB1, and CKB2, and the clear signal CLR of FIG. 1, clock signals (drive signals) CKA13, CKA23, CKB13, and CKB23, and the clear signal CLR3 are input in this order.

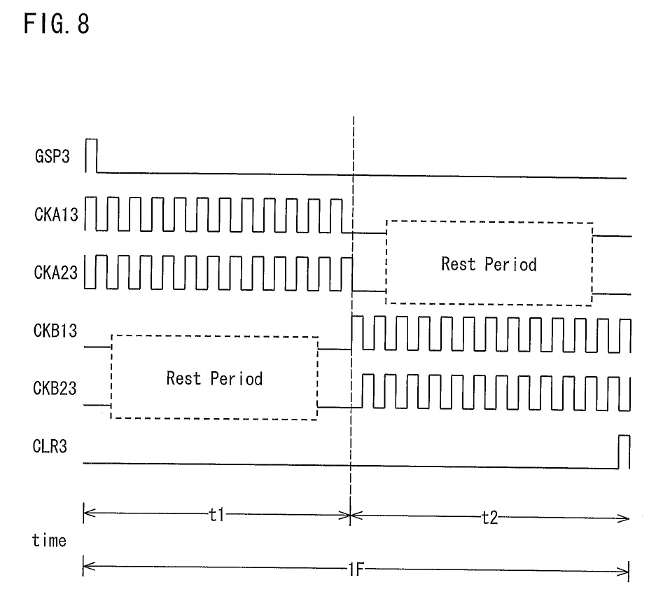

As illustrated in FIG. 8, the clock signals CKA13 and CKA23 are signals obtained by replacing the period t2 of the clock signals CKA1 and CKA2 with a rest period in which a non-active level is maintained. The clock signals CKB13 and CKB23 are signals obtained by replacing the period t1 of the clock signals CKB1 and CKB2 with a rest period in which a non-active level is maintained. The clear signal CLR3 is a signal which becomes an active level only in a final clock pulse period of 1 frame period (1F), and is supplied only to a reset terminal of the shift register stage SRn which is the final stage of the second circuit section 2b.

As shown by (1) of FIG. 7, the gate scan is performed in a direction from the D2 side towards the D1 side in the period t1 and performed in the direction from the D2 side towards the D1 side in the period t2.

Accordingly, the clock signals CKA13 and CKA23 charge/discharge the wires 10b and 10c only in the period t1 which is an operation period of the first circuit section 2a, and the clock signals CKB13 and CKB23 charge/discharge the wires 10e and 10f only in the period t2 which is an operation period of the second circuit section 2b. This greatly reduces a loss of electricity associated with charging/discharging of the supply wires for supplying a drive signal, thereby further reducing waveform deformation.

Further, a reduction in power consumption can be achieved since the first circuit section 2a stops its operation in the period t2 and the second circuit section 2b stops its operation in the period t1.

Further, the number of start pulse signals (here, gate start pulse signals) declines since a shift pulse that is output from a shift register stage which is the final stage of one circuit section is supplied, as a shift pulse, to a shift register stage which is an initial stage of another circuit section. This allows a reduction in electricity for supplying the start pulse signals and a reduction in the number of wires for supplying the start pulse signals. The reduction in the number of wires for supplying the start pulse signals allows a reduction in area.

### Example 5

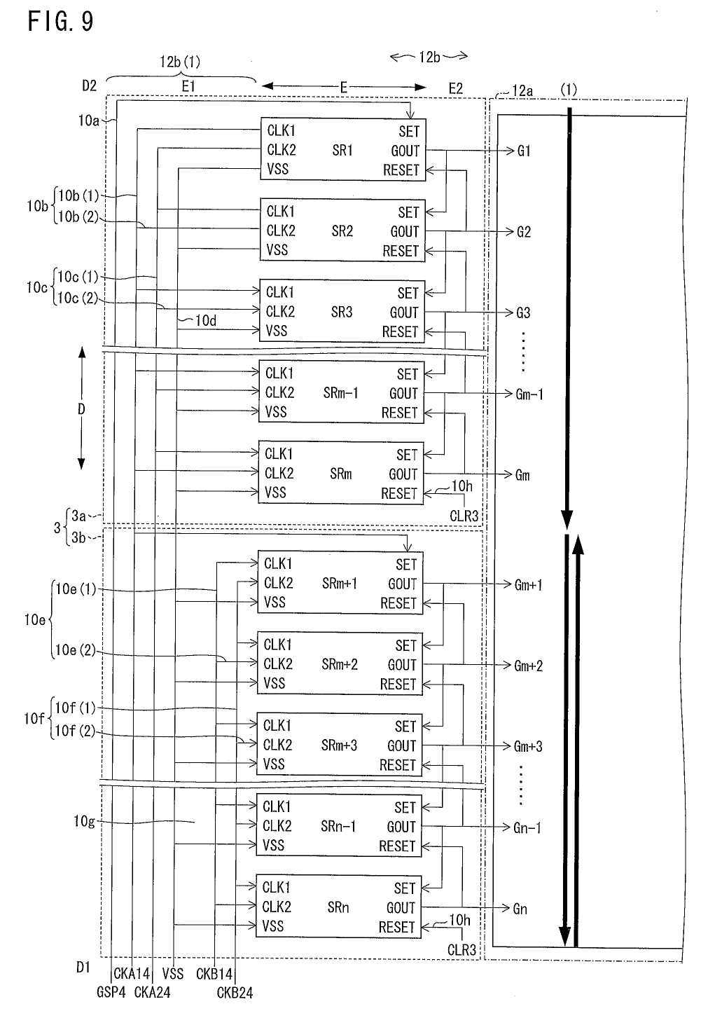

FIG. 9 illustrates a configuration of a shift register circuit 3 of the present example.

The shift register circuit 3 of FIG. 9 includes a first circuit section 3a and a second circuit section 3b.

The first circuit section 3a has an identical configuration to the first circuit section 1a of FIG. 1. To a set terminal SET of a shift register stage SR1 which is an initial stage of the first circuit section 2a, a gate start pulse signal GSP4 that is identical to the gate start pulse signal GSP1 is supplied. The second circuit section 3b is different from the second circuit section 1b of FIG. 1 in that a clock signal CKA14 described below is input instead of the gate start pulse signal GSP2.

Further, instead of the clock signals CKA1, CKA2, CKB1, and CKB2, and the clear signal CLR of FIG. 1, clock signals (drive signals) CKA14, CKA24, CKB14, and CKB24, and the clear signal CLR3 are input, respectively.

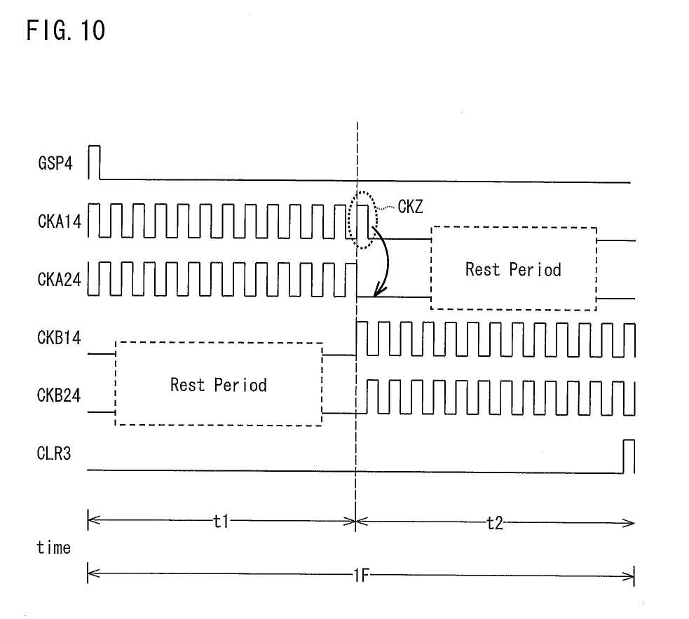

As illustrated in FIG. 10, the clock signal CKA14 operates in the period t1 of the clock signal CKA1 and operates at an active level in a period of an initial clock pulse CKZ of the period t2, whereas, in a remaining period of the period t2, the clock signal CKA14 is in a rest period in which a non-active level is maintained. The clock signal CKA24 is a signal obtained by replacing the period t2 of the clock signal CKA2 with a rest period in which a non-active level is maintained. The clock signals CKB14 and CKB24 are signals obtained by replacing the period t1 of the clock signals CKB1 and CKB2 with a rest period in which a non-active level is maintained. The clear signal CLR3 is a signal which becomes an active level only in a final clock pulse period of 1 frame period (1F).

As illustrated in (1) of FIG. 9, the gate scan is performed in a direction from the D2 side towards the D1 side in the period t1 and performed in the direction from the D2 side towards the D1 side in the period t2. In the period t1, the second circuit section 1b stops its operation since the clock signals CKB14 and CKB24 are in a rest period. At the time of shift into the period t2, the clock pulse CKZ of the clock signal CKA14 is supplied, as a gate start pulse signal, to a set terminal SET of a shift register stage SRm+1 which is the initial stage of the second circuit section 3b. In this way, the second circuit section 3b starts a shift operation.

In FIG. 9, a shift pulse may be shifted from the D1 side towards the D2 side as follows. Specifically, the clock pulse CKZ of the clock signal CKA14 is supplied to a shift register stage SRn of the second circuit section 3b in a manner reverse to the order of cascade connection, instead of supplying a pulse of the clock signal CKA14 to the shift register stage SRm+1 which is the initial stage of the second circuit section 3b. In this case, the clear signal CLR3 is supplied to a reset terminal RESET of the shift register stage SRm+1 of the second circuit section 3b.

According to the arrangement of the present example, the clock signals CKA14 and CKA24 charge/discharge the wires 10b and 10c only in the period t1 which is an operation period of the first circuit section 3a, and the clock signals CKB14 and CKB24 charge/discharge the wires 10e and 10f only in the period t2 which is an operation period of the second circuit section 3b. This greatly reduces a loss of electricity associated with charging/discharging of the supply wires for supplying a drive signal, thereby further reducing waveform deformation.

Further, a reduction in power consumption can be achieved since the first circuit section 3a stops its operation in the period t2 and the second circuit section 3b stops its operation in the period t1.

Further, the number of start pulse signals (here, gate start pulse signals) of the shift register circuit 1 declines since the last pulse before shift into a rest period out of pulses of a drive signal having a rest period is input as a shift pulse of an i-th circuit section. This allows a reduction in electricity for supplying the start pulse signals and a reduction in the number of wires for supplying the start pulse signals. The reduction in the number of wires for supplying the start pulse signals allows a reduction in area.

Examples have been described.

There are variations in gate scan direction and in data signal supply direction, as described above. The configuration of the liquid crystal display device 11 may be appropriately modified as illustrated in (a) through (c) of FIG. 12 in accordance with these variations.

(a) of FIG. 12 illustrates an arrangement in which (i) the gate scan of each of the first through N-th circuit sections is performed in a direction from a side close to the source driver 16 provided in an upper part of the display panel 12 towards a side far from the source driver 16 or in a direction from the side far from the source driver 16 towards the side close to the source driver 16 and (ii) a data signal is supplied in a direction from the side close to the source driver 16 towards the side far from the source driver 16.

(b) of FIG. 12 illustrates an arrangement in which (i) the gate scan of each of the first through N-th circuit sections is performed in a direction from a side close to the source driver 16 provided in a lower part of the display panel 12 towards a side far from the source driver 16 or in a direction from the side far from the source driver 16 towards the side close to the source driver 16 and (ii) a data signal is supplied in a direction from the side close to the source driver 16 towards the side far from the source driver 16.

(c) of FIG. 12 illustrates an arrangement in which (i) a screen is divided into a first screen, which is an upper screen, and a second screen, which is a lower screen, (ii) the first through N-th circuit sections are allocated to the upper screen (first screen) and the lower screen (second screen), and (iii) a control board 14a, a flexible printed circuit board 13a, a source driver (first data signal line driving circuit) 16a, each of which is for the upper screen and a control board 14b, a flexible printed circuit board 13b, a source driver (second data signal line driving circuit) 16b, each of which is for the lower screen are provided. In this case, the gate scan and the data signal supply may be performed in a direction from a side close to a corresponding source driver to a side far from the corresponding source driver. The gate scan may be performed in any of the directions both in the upper and lower screens.

Further, the display device may be another display device such as an EL display device.

As described above, a shift register circuit of the present invention includes: first through N-th circuit sections (N is an integer equal to or larger than 2) in each of which a plurality of shift register stages are connected in cascade; and supply wires, each of the first through N-th circuit sections receiving a drive signal for driving the plurality of shift register stages via a supply wire exclusive for said each of the first through N-th circuit sections out of the supply wires.

According to the invention, the number of intersections of each of the supply wires for supplying a drive signal and another wire greatly declines. This makes it possible to greatly reduce the capacitances of cross capacitors per supply wire for supplying a drive signal. Further, the number of shift register stages connected to each of the supply wires for supplying a drive signal greatly declines. This allows a great reduction in sum of parasitic capacitors in connection parts with the shift register stages. Accordingly, a drive signal that is supplied from a drive signal source to each of the supply wires for supplying a drive signal can have a waveform with smaller deformation, and therefore a waveform of an output signal from each of the shift register stages can have a waveform with smaller deformation, as compared with a conventional art. Consequently, it is possible to increase a charging ratio of a load without increasing a voltage range of the drive signal source nor increasing a transistor size (channel width), thereby increasing an operation margin of the shift register stages.

It is thus possible to provide a shift register circuit that makes it possible to secure a sufficient operation margin.

The shift register circuit of the present invention is arranged such that a direction along a shift direction is a first direction and a direction perpendicular to the first direction on a surface on which the shift register circuit is provided is a second direction, the first through N-th circuit sections are aligned in the first direction, the number of shift register stages is determined for each of the first through N-th circuit sections, and each of the supply wires which corresponds to one of the first through N-th circuit sections is provided in a first region that is located closer, than the corresponding one of the first through N-th circuit sections, to a predetermined side of the second direction, which is one side of the second direction and which is common to all of the first through N-th circuit sections, so as to extend from a predetermined side of the first direction, which is one side of the first direction and which is common to all of the first through N-th circuit sections, towards the corresponding one of the first through N-th circuit sections.

According to the invention, it is possible to provide a shift register circuit that makes it possible to secure a sufficient operation margin in a case where a drive signal source is provided only on the predetermined side of the first direction.

The shift register circuit of the present invention is arranged such that each of the supply wires has a main wire that extends in the first direction and branch wires each of which branches off from the main wire towards a corresponding one of the first through N-th circuit sections so as to be connected to the corresponding one of the first through N-th circuit sections.

According to the invention, it is possible to greatly reduce the capacitances of cross capacitors formed as a result of presence of the main wire and the branch wires.

The shift register circuit of the present invention is arranged such that out of the supply wires, a supply wire corresponding to one of the first through N-th circuit sections which one is farther from the predetermined side of the first direction when viewed from a direction along the first direction has a main wire that is closer to the predetermined side of the second direction in the first region.

According to the invention, it is possible to minimize the number of parts where a cross capacitor is formed, in a case where a drive signal source is provided only on the predetermined side of the first direction.

The shift register circuit of the present invention is arranged such that a direction along a shift direction is a first direction and a direction perpendicular to the first direction on a surface on which the shift register circuit is provided is a second direction, each of the supply wires which corresponds to one of the first through N-th circuit sections is provided in a first region that is located closer, than the corresponding one of the first through N-th circuit sections, to a predetermined side of the second direction, which is one side of the second direction and which is common to for all of the first through N-th circuit sections, so that, out of the supply wires, (i) a supply wire corresponding to one of the first through N-th circuit sections which one is provided closer to a predetermined side of the first direction which is one side of the first direction extends from the predetermined side of the first direction towards the corresponding one of the first through N-th circuit sections and (ii) a supply wire corresponding to one of the first through N-th circuit sections which one is provided closer to an opposite side to the predetermined side of the first direction extends from the opposite side to the predetermined side of the first direction towards the corresponding one of the first through N-th circuit sections.

According to the invention, a balance can be achieved between lengths of supply wires on the predetermined side of the first direction of the shift register circuit and lengths of supply wires on the opposite side to the predetermined side of the first direction. Accordingly, a difference is unlikely occur in deformation of a waveform of a drive signal, and therefore a difference is unlikely occur in deformation of a waveform of an output signal of each of the shift register stages.

The shift register circuit of the present invention is arranged such that each of the supply wires has a main wire that extends in the first direction and branch wires each of which branches off from the main wire towards a corresponding one of the first through N-th circuit sections so as to be connected to the corresponding one of the first through N-th circuit sections.

According to the invention, it is possible to greatly reduce the number of cross capacitors formed as a result of presence of the main wire and the branch wires.

The shift register circuit of the present invention is arranged such that the drive signal for one of the first through N-th circuit sections has a rest period within an operation period of another one of the first through N-th circuit sections.

According to the invention, the presence of the rest period reduces a loss of electricity associated with charging/discharging in the supply wires for supplying a drive signal, thereby further reducing waveform deformation. Further, a reduction in power consumption can be achieved since an operation of a corresponding one of the first through N-th circuit sections is stopped.

The shift register circuit of the present invention is arranged such that out of pulses of the drive signal having the rest period, a last pulse before shift into the rest period is input as a shift pulse for one of the first through N-th circuit sections.

According to the invention, out of pulses of a drive signal having a rest period, a last pulse before shift into the rest period is input as a shift pulse of one of the first through N-th circuit sections. Accordingly, the number of start pulses of the shift register circuit declines. This allows a reduction in electricity for supplying the start pulse signals and a reduction in the number of wires for supplying the start pulse signals. The reduction in the number of wires for supplying the start pulse signals allows a reduction in area.

The shift register circuit of the present invention is arranged such that a shift pulse that is output from a shift register stage which is a final stage of one of the first through N-th circuit sections is supplied, as a shift pulse, to a shift register stage which is an initial stage of another one of the first through N-th circuit sections.

According to the invention, a shift pulse that is output from a shift register stage which is a final stage of one of the first through N-th circuit sections is supplied, as a shift pulse, to a shift register stage which is an initial stage of another one of the first through N-th circuit sections. Accordingly, the number of start pulse signals declines. This allows a reduction in electricity for supplying the start pulse signals and a reduction in the number of wires for supplying the start pulse signals. The reduction in the number of wires for supplying the start pulse signals allows a reduction in area.

The shift register circuit of the present invention is arranged such that the shift register circuit is formed from at least one of amorphous silicon, polycrystalline silicon, CG silicon, microcrystalline silicon, and amorphous oxide semiconductor.

According to the invention, the shift register circuit can be monolithically built into a device formed with the use of such a material.

A display device of the present invention includes the shift register circuit.

According to the invention, it is possible to provide a display device which allows a large operation margin and high-quality display.

The display device of the present invention further includes: a screen that is divided into a first screen and a second screen, each of the first through N-th circuit sections being allocated to the first screen or the second screen; a first data signal line driving circuit for supplying a data signal corresponding to the first screen; and a second data signal line driving circuit for supplying a data signal corresponding to the second screen.

According to the invention, the upper and lower screens thus divided can be driven by the first through N-th circuit sections, each of which is allocated to the upper screen or the lower screen, with the use of a drive signal having a long cycle. This makes it possible to secure a long selection period of a picture element. Consequently, high resolution and high-speed display can be achieved well.

A method of the present invention for driving a shift register circuit which includes first through N-th circuit sections (N is an integer equal to or larger than 2) in each of which a plurality of shift register stages are connected in cascade, includes the step of supplying, to each of the first through N-th circuit sections, a drive signal for driving the plurality of shift register stages via a supply wire exclusive for said each of the first through N-th circuit sections.

According to the invention, it is possible to provide a method for driving a shift register circuit that makes it possible to secure a sufficient operation margin.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

The present invention is suitably applicable to an active matrix display device.

### REFERENCE SIGNS LIST

1: Shift register circuit
1a: First circuit section (i-th circuit section)
1b: Second circuit section (i-th circuit section)
2a: First circuit section (i-th circuit section)
2b: Second circuit section (i-th circuit section)
3a: First circuit section (i-th circuit section)
3b: Second circuit section (i-th circuit section)
10b: Wire (supply wire)
10c: Wire (supply wire)
10e: Wire (supply wire)
10f: Wire (supply wire)
10b(1): Main wire
10c(1): Main wire
10e(1): Main wire
10f(1): Main wire
10b(2): Branch wire
10c(2): Branch wire
10e(2): Branch wire
10f(2): Branch wire
11: Liquid crystal display device (display device)
12: Display panel
12a: Active region
12b(1): Region (first region)
16a: Source driver (first data signal line driving circuit)
16b: Source driver (second data signal line driving circuit)
SRk: Stage (shift register stage)
CKA1, CKA2, CKB1, CKB2: Clock signal (drive signal)
CKA12, CKA22, CKB12, CKB22: Clock signal (drive signal)
CKA13, CKA23, CKB13, CKB23: Clock signal (drive signal)
CKA14, CKA24, CKB14, CKB24: Clock signal (drive signal)
D: Direction (first direction)
D1: (Side) (predetermined side of first direction)
D2: (Side) (opposite side to a predetermined side of first direction)
E: Direction (second direction)
E1: (Side) (predetermined side of second direction)

1. A shift register circuit comprising:
first through N-th circuit sections (N is an integer equal to or larger than 2) in each of which a plurality of shift register stages are connected in cascade; and
supply wires,
each of the first through N-th circuit sections receiving a drive signal for driving the plurality of shift register stages via a supply wire exclusive for said each of the first through N-th circuit sections out of the supply wires.

2. The shift register circuit according to claim 1, wherein:
a direction along a shift direction is a first direction and a direction perpendicular to the first direction on a surface on which the shift register circuit is provided is a second direction,
the first through N-th circuit sections are aligned in the first direction,
the number of shift register stages is determined for each of the first through N-th circuit sections, and
each of the supply wires which corresponds to one of the first through N-th circuit sections is provided in a first region that is located closer, than the corresponding one of the first through N-th circuit sections, to a predetermined side of the second direction, which is one side of the second direction and which is common to all of the first through N-th circuit sections, so as to extend from a predetermined side of the first direction, which is one side of the first direction and which is common to all of the first through N-th circuit sections, towards the corresponding one of the first through N-th circuit sections.

3. The shift register circuit according to claim 2, wherein:
each of the supply wires has a main wire that extends in the first direction and branch wires each of which branches off from the main wire towards a corresponding one of the first through N-th circuit sections so as to be connected to the corresponding one of the first through N-th circuit sections.

4. The shift register circuit according to claim 3, wherein:
out of the supply wires, a supply wire corresponding to one of the first through N-th circuit sections which one is farther from the predetermined side of the first direction when viewed from a direction along the first direction has a main wire that is closer to the predetermined side of the second direction in the first region.

5. The shift register circuit according to claim 1, wherein:
a direction along a shift direction is a first direction and a direction perpendicular to the first direction on a surface on which the shift register circuit is provided is a second direction,
each of the supply wires which corresponds to one of the first through N-th circuit sections is provided in a first region that is located closer, than the corresponding one of the first through N-th circuit sections, to a predetermined side of the second direction, which is one side of the second direction and which is common to all of the first through N-th circuit sections, so that, out of the supply wires, (i) a supply wire corresponding to one of the first through N-th circuit sections which one is provided closer to a predetermined side of the first direction which is one side of the first direction extends from the predetermined side of the first direction towards the corresponding one of the first through N-th circuit sections and (ii) a supply wire corresponding to one of the first through N-th circuit sections which one is provided closer to an opposite side to the predetermined side of the first direction extends from the opposite side to the predetermined side of the first direction towards the corresponding one of the first through N-th circuit sections.

6. The shift register circuit according to claim 5, wherein:
each of the supply wires has a main wire that extends in the first direction and branch wires each of which branches off from the main wire towards a corresponding one of the first through N-th circuit sections so as to be connected to the corresponding one of the first through N-th circuit sections.

7. The shift register circuit according to claim 1, wherein:
the drive signal for one of the first through N-th circuit sections has a rest period within an operation period of another one of the first through N-th circuit sections.

8. The shift register circuit according to claim 7, wherein:
out of pulses of the drive signal having the rest period, a last pulse before shift into the rest period is input as a shift pulse for one of the first through N-th circuit sections.

9. The shift register circuit according to claim 1, wherein:
a shift pulse that is output from a shift register stage which is a final stage of one of the first through N-th circuit sections is supplied, as a shift pulse, to a shift register stage which is an initial stage of another one of the first through N-th circuit sections.

10. The shift register circuit according to claim 1, wherein:
the shift register circuit is formed from at least one of amorphous silicon, polycrystalline silicon, CG silicon, microcrystalline silicon, and amorphous oxide semiconductor.

11. A display device comprising a shift register circuit as set forth in claim 1.

12. A display device according to claim 11, further comprising:
a screen that is divided into a first screen and a second screen, each of the first through N-th circuit sections being allocated to the first screen or the second screen;
a first data signal line driving circuit for supplying a data signal corresponding to the first screen; and
a second data signal line driving circuit for supplying a data signal corresponding to the second screen.

13. A method for driving a shift register circuit which includes first through N-th circuit sections (N is an integer equal to or larger than 2) in each of which a plurality of shift register stages are connected in cascade,
the method comprising the step of supplying, to each of the first through N-th circuit sections, a drive signal for driving the plurality of shift register stages via a supply wire exclusive for said each of the first through N-th circuit sections.
